(19) United States
(12) Patent Application Publication
(10) Pub. No.: US 2020/0012086 A1
(43) Pub. Date: Jan. 9, 2020

(54) OPTICAL MODULE AND ENDOSCOPE

(71) Applicant: OLYMPUS CORPORATION, Tokyo (JP)

(72) Inventor: Kosuke KAWAHARA, Kamiina-gun (JP)

(73) Assignee: OLYMPUS CORPORATION, Tokyo (JP)

(21) Appl. No.: 16/509,681

(22) Filed: Jul. 12, 2019

Related U.S. Application Data
(63) Continuation of application No. PCT/JP2017/001657, filed on Jan. 19, 2017.

(51) Int. Cl. G02B 23/26; H05K 1/18; G02B 6/42

(52) U.S. Cl. CPC G02B 23/26; H05K 1/181; G02B 6/428; H05K 2201/10121; G02B 6/4239; H05K 2201/09072; G02B 6/4212

(57) ABSTRACT

An optical module includes: an optical element having a light emitting portion for emitting optical signals, and an external electrode on a top face; a wiring board having a connection electrode bonded to the external electrode of the optical element on the first main face, and having a through hole serving as an optical path of the optical signals; an optical fiber for transmitting the optical signals arranged at a position coupled optically to the optical element; a resin layer sealing a bonding portion between the external electrode and the connection electrode, constituting a wall surrounding the optical path; and transparent resin filling the optical path. The transparent resin is expanded around the resin layer via at least one gap of the resin layer.

### CROSS REFERENCE TO RELATED APPLICATION

This application is a continuation application of PCT/JP2017/001657 filed on Jan. 19, 2017, the entire contents of which are incorporated herein by this reference.

### BACKGROUND OF THE INVENTION

### 1. Field of the Invention

The present invention relates to an optical module on which transparent resin is arranged between an optical element and a light waveguide, and an endoscope having the optical module.

### 2. Description of the Related Art

An endoscope has an image pickup device such as a CCD at a distal end portion of an elongated flexible insertion portion. In recent years, it has been considered to use an image pickup device with high resolution in an endoscope in order to display a high-quality image. When the image pickup device with the high resolution is used, the amount of signals transmitted to a signal processing device (processor) from the image pickup device increases, so that there is such a risk that the insertion portion becomes thick due to a wiring in transmitting electric signals via a metal wiring by electric signals.

Optical signal transmission via a thin optical fiber by optical signals instead of the electric signals is preferred to make the insertion portion to have a smaller diameter and low invasiveness. An E/O type optical module (electricity-light converter) for converting the electric signals to the optical signals, and an O/E type optical module (light-electricity converter) for converting the optical signals to the electric signals are used to transmit the optical signals.

In the optical module, light coupling efficiency to the optical fiber (light waveguide) for transmitting optical elements and optical signals is essential. In order to improve the light coupling efficiency, it is effective to fill transparent resin that is a refraction index matching material between the optical element and the optical fiber.

Japanese Patent Application Laid-Open Publication No. 2012-203115 discloses an optical coupling element that exhausts to outside air bubbles contained in transparent resin that is a refraction index matching material by arranging optical elements so as not to completely block a top of an opening of a retaining hole in which an optical fiber is inserted.

### SUMMARY OF THE INVENTION

An optical module in an embodiment of the present invention includes an optical element having a light function region for emitting or receiving optical signals, and an external electrode on a top face; a wiring board having a first main face and a second main face, having a connection electrode bonded to the external electrode of the optical element on the first main face, and having a through hole serving as an optical path of the optical signals; a light waveguide for transmitting the optical signals, the light waveguide being arranged at a position coupled optically to the optical element; a resin layer sealing a bonding portion between the external electrode and the connection electrode, constituting a wall surrounding the optical path, and having at least one gap serving as a break on the wall; and transparent resin filling the optical path between the optical element and the light waveguide. The transparent resin is expanded around the resin layer via at least one gap of the resin layer.

An endoscope in another embodiment has an optical module, and the optical module includes an optical element having a light function region for emitting or receiving optical signals, and an external electrode on a top face; a wiring board having a first main face and a second main face, having a connection electrode bonded to the external electrode of the optical element on the first main face, and having a through hole serving as an optical path of the optical signals; a light waveguide for transmitting the optical signals, the light waveguide being arranged at a position coupled optically to the optical element, a resin layer sealing a bonding portion between the external electrode and the connection electrode, constituting a wall surrounding the optical path, and having at least one gap serving as a break on the wall; and transparent resin filling the optical path between the optical element and the light waveguide. The transparent resin is expanded around the resin layer via at least one gap of the resin layer.

### BRIEF DESCRIPTION OF THE DRAWINGS

FIG. 1 is an exploded view of an optical module in a first embodiment;

FIG. 2A is a perspective view for explaining a method for manufacturing the optical module in the first embodiment;

FIG. 2B is a cross section view along a line IIB-IIB of FIG. 2A for explaining the method for manufacturing the optical module in the first embodiment;

FIG. 2C is a cross section view along a line IIC-IIC of FIG. 2A for explaining the method for manufacturing the optical module in the first embodiment;

FIG. 3A is a cross section view for explaining the method for manufacturing the optical module in the first embodiment;

FIG. 3B is a cross section view for explaining the method for manufacturing the optical module in the first embodiment;

FIG. 4 is a top transparent view of the optical module in the first embodiment;

FIG. 5 is a top transparent view of an optical module in Modification 1 in the first embodiment;

FIG. 6A is a top transparent view of the optical module in Modification 2 in the first embodiment;

FIG. 6B is a cross section view of the optical module in Modification 2 in the first embodiment;

FIG. 7 is a top transparent view of an optical module in a second embodiment;

FIG. 8A is a cross section view for explaining a method for manufacturing an optical module in a third embodiment;

FIG. 8B is a cross section view of the optical module in the third embodiment;

FIG. 9A is a cross section view for explaining a method for manufacturing an optical module in a fourth embodiment;

FIG. 9B is a cross section view of the optical module in the fourth embodiment;

FIG. 10 is a cross section view of an optical module in a fifth embodiment;

and

FIG. 11 is a perspective view of an endoscope in a sixth embodiment.

### DETAILED DESCRIPTION OF THE PREFERRED EMBODIMENTS

### First Embodiment

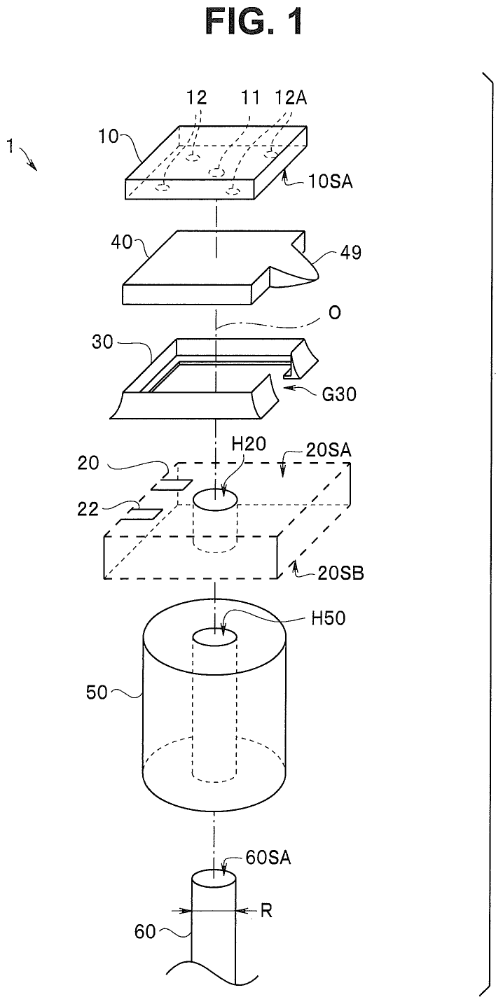

An optical module 1 in the present invention will be explained with reference to FIG. 1. In following explanation, it is noted that drawings based on each embodiment are merely schematic, a relationship between thickness and width of respective portions and a ratio of thickness of each portion, etc. are different from actual ones, and portions in which dimensional relationship and ratio are different from each other might be included in respective drawings. Illustration and numbering of some components might be omitted.

An optical module 1 in the present invention is an E/O module for converting electric signals to optical signals, and transmitting the optical signals. The optical module 1 has an optical element 10, a wiring board 20, a ferrule 50, and an optical fiber 60 that is a light waveguide for transmitting the optical signals.

The optical element 10 is a light emitting element having a light emitting portion 11 that is a light function region for outputting lights of the optical signals, for example, VCSEL (Vertica Cavity Surface Emitting LASER). For example, a micro-size optical element 10 with plane view size of 250 μm×450 μm has a light emitting portion 11 with a diameter of 25 μm, and two external electrodes 12 with a diameter of 80 μm for supplying driving signals to the light emitting portion 11 on a light emitting face 10SA that is a top face. A dummy external electrode 12A with the same configuration as that of the external electrode 12 is also arranged on the light emitting face 10SA.

The wiring board 20 has a first main face 20SA, and a second main face 20SB opposite to the first main face 20SA. The optical elements 10 are mounted on the first main face 20SA. In other words, the wiring board 20 has a connection electrode 22 bonded to the external electrode 12 including bumps of the optical element 10 on the first main face 20SA. Driving signals are transmitted to the connection electrode 22 via a wiring (not shown). A through hole H20 serving as an optical path of optical signals outputted by the optical element 10 is provided at a position of the wiring board 20 opposite to the light emitting portion 11 of the optical element 10.

A substrate of the wiring board 20 is, for example, made of polyimide with thickness of 25 μm. The substrate of the wiring board 20 may be a ceramic substrate, a glass epoxy substrate, a glass substrate, a silicon substrate or the like.

A cylindrical ferrule 50 is provided with an insertion hole H50 in which a distal end portion of the optical fiber 60 is inserted. The ferrule 50 is positioned so that a center shaft of the insertion hole H50 is matched with a center shaft of the through hole H20 of the wiring board 20, and is arranged on the second main face 20SB of the wiring board 20. The insertion hole H50 of the ferrule 50 and the through hole H20 of the wiring board 20 have almost the same inside diameter.

An opening diameter of the through hole H20 on the second main face 20SB is also almost the same as an inside diameter of the insertion hole H50, and is larger than an outside diameter R of the optical fiber 60. An opening diameter of the first main face 20SA of the through hole H20 is smaller than the outside diameter R of the optical fiber 60. In other words, the inside diameter of the through hole H20 varies in a depth direction. The optical fiber 60 penetrates through the insertion hole H50 and is also inserted in the through hole H20, and is in contact with a portion at which the inside diameter of the through hole H20 is smaller than the outside diameter of the optical fiber 60, on its distal end face, so as to define a distance from the optical element 10.

A distance between a distal end face of the optical fiber 60 and the optical element 10 may be defined by the through hole H20 with the inside diameter smaller than a diameter R of the optical fiber 60. In this case, the optical fiber 60 is not inserted in the through hole H20. The optical fiber 60 may be inserted in the through hole H20.

The optical fiber 60 is, for example, a light waveguide having an outside diameter R of 125 μm, and including a core with light transmission outside diameter of 50 μm, and a clad covering an outer periphery of the core. The light optical fiber 60 for transmitting optical signals is inserted in the insertion hole H50 of the ferrule 50, and is arranged at a position optically coupled to the optical element 10 via the through hole H20.

In the optical module 1, the optical element 10 and the wiring board 20 are adhered to each other by a resin layer 30 that is adhesive. The resin layer 30 sealing the bonding portion between the external electrode 12 and a connection electrode 22 has a U-shaped cross section orthogonal to the optical path. In other word, the resin layer 30 is a wall arranged to surround the optical path of the optical signals, but is not continued, and has a gap (break) G30.

The resin layer 30 is a side fill material injected to a gap between a side face of the optical element 10 and the bonding portion, after bonding the optical element 10 and the wiring board 20. The resin layer 30 is made of a light shielding material in which light shielding materials such as dye or nonconductive black-based pigment are mixed with resin. In the case where influences by light passing through the resin layer 30 are small, the resin layer 30 is not necessarily made of a light shielding material, and the resin layer 30 may have translucency.

For example, acrylic based resin, epoxy based resin, vinyl based resin, ethylene based resin, silicone based resin, urethane based resin, polyamide based resin, fluorine based resin, polybutadiene based resin, or polycarbonate based resin may be used for resin of the resin layer 30. Among them, the acrylic based resin and the epoxy based resin are suitable for the resin layer 30 in view of humidity resistance, heat resistance, detachment resistance and shock resistance.

An optical path between the optical element 10 and the optical fiber 60 is filled with transparent resin 40 that is a refraction index matching material. The transparent resin 40 has almost the same refraction index as that of a core of the optical fiber 60 that is a light waveguide. For example, acrylic based resin, epoxy based resin, vinyl based resin, ethylene based resin, silicone based resin, urethane based resin, polyamide based resin, fluorine based resin, polybutadiene based resin, or polycarbonate based resin may be used for the transparent resin 40. Among them, the acrylic based resin and the epoxy based resin are suitable in view of humidity resistance, heat resistance, detachment resistance and shock resistance.

When the resin layer 30 has translucency, the resin of the resin layer 30 and the resin of the transparent resin 40 may be the same. The same resin of the transparent resin 40 mixed with the light shielding material may also be used as the resin of the resin layer 30. When the resin of the resin layer 30 and the resin of the transparent resin 40 are the same, adhesion strength of both resins is high, and heat expansion coefficients of both resins are the same, so that reliability is high.

In the optical module 1, the transparent resin 40 is expanded around the resin layer 30 via a gap G30 of the resin layer 30. In other words, transparent resin 49 at part of the transparent resin 40 projects from the gap G30 of the resin layer 30.

As described below, in the optical module 1, there is no air bubble in the transparent resin 40 filling the optical path between the optical element 10 and the optical fiber 60. Therefore, the optical module 1 has high light coupling efficiency of the optical element 10 and the optical fiber 60. Furthermore, the optical module 1 in which the resin layer 30 surrounding the optical path has a light shielding property is hardly influenced by outside light, and has high transmission quality.

### (Manufacturing Method)

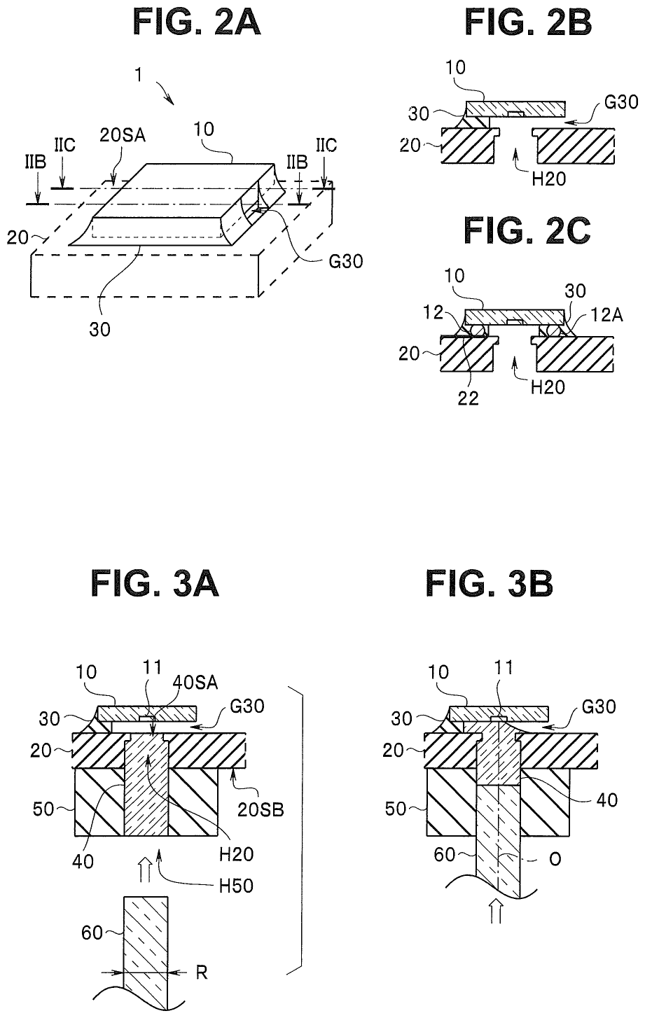

Then, a method for manufacturing an optical module 1 will be explained with reference to FIG. 2A to FIG. 3B.

FIG. 2A, FIG. 2B and FIG. 2C are drawings for explaining a condition before liquid transparent resin 40 is injected, and show the optical module 1 during manufacturing, in which the optical element 10 is bonded to the first main face 20SA of the wiring board 20 and adhered and sealed by the resin layer 30 that is a side fill material.

First, the light emitting portion 11 of the optical element 10 and the through hole H20 of the wiring board 20 are positioned. For example, an Au bump with height of 15 μm that is the external electrode 12 of the optical element 10 is ultrasound-bonded to the connection electrode 22 made of Au-boarded copper of the wiring board 20. After solder paste and the like are printed on the connection electrode 22 and the optical element 10 is arranged, the solder may be molten and bonded by reflow and the like. When the external electrode 12 is an Au/Sn bump, the external electrode 12 may be thermocompression bonded to the connection electrode 22.

The external electrode 12 is not necessarily a bump, but the connection electrode 22 may be a bump instead. When the connection electrode 22 is a bump, the external electrode 12 is a terminal pad formed on a light emitting face 10SA of the optical element 10.

The dummy external electrode 12A includes a bump with the same height as the external electrode 12, so that the light emitting face 10SA of the optical element 10 and the first main face 20SA of the wiring board 20 are arranged in parallel to each other. The wiring board 20 may include a processing circuit, for example, for converting electric signals into driving signals of the optical element 10.

The optical element 10 is fixed to the wiring board 20 via the bonding portion (bump). However, the strength of the bonding portion is not sufficient. It is also preferable that the bonding portion be sealed for improving reliability.

In the optical module 1, the adhesion strength of the optical element 10 and the wiring board 20 is reinforced by the resin layer 30 that is a side fill, and the bonding portion is sealed. For example, there is a gap of 15 μm between the light emitting face 10SA of the optical element 10 and the first main face 20SA of the wiring board 20 bonded via the bump with the height of 15 μm. The liquid resin layer 30 is injected to the gap between the side face and the light emitting face 10SA of the optical element 10 and the first main face 20SA, and hardened to form the resin layer 30.

The liquid resin layer 30 is arranged around the optical element 10 to surround an optical path. However, it is not arranged at part around the optical element 10, in order to form a U-shape. In order not to block the optical path, an appropriate amount of the side fill material is arranged.

Light shielding materials such as dye or nonconductive black pigment are mixed with the resin of the resin layer 30. The nonconductive black pigment includes aniline black, cyanine black, titanium black, black iron oxide, chromium oxide, manganese oxide or the like. In the case where influences by light passing through the resin layer 30 are small, the resin layer 30 is not necessarily made of a light shielding material, and the resin layer 30 may have translucency.

As shown in FIG. 3A, the ferrule 50 is arranged on the second main face 20SB of the wiring board 20. The cylindrical ferrule 50 has a columnar insertion hole H50 with an inside diameter almost the same as an outside diameter R of the optical fiber 60 to be inserted. The insertion hole H50 may have a prism-like shape instead of a columnar shape, as long as the optical fiber 60 can be held on its inner face. A material of the ferrule 50 is a metal member such as ceramic, Si, glass or SUS. The ferrule 50 may have an almost rectangular solid shape, a conical shape, or the like. The insertion hole H50 may also have a tapered shape such that a diameter of at least one opening is larger than a diameter of a center portion.

The ferrule 50 is fixed to the second main face 20SB of the wiring board 20, while an extension line of an optical axis O of the optical fiber 60 inserted in the insertion hole H50 is positioned to pass through a center of the light emitting portion 11 of the optical element 10.

As shown in FIG. 3A, uncured liquid transparent resin 40 is injected to the insertion hole H50. The inside diameters of the insertion hole H50 and the through hole H20 are slightly larger than the outside diameter R of the inserted optical fiber 60. For example, when the outside diameter R of the optical fiber 60 is 125 μm, the inside diameter of the insertion hole H50 is 130 μm to 150 μm, and extremely thin.

Therefore, the insertion hole H50 and the through hole H20 are filled with the liquid transparent resin 40 by a capillary action due to an interface tension against a wall.

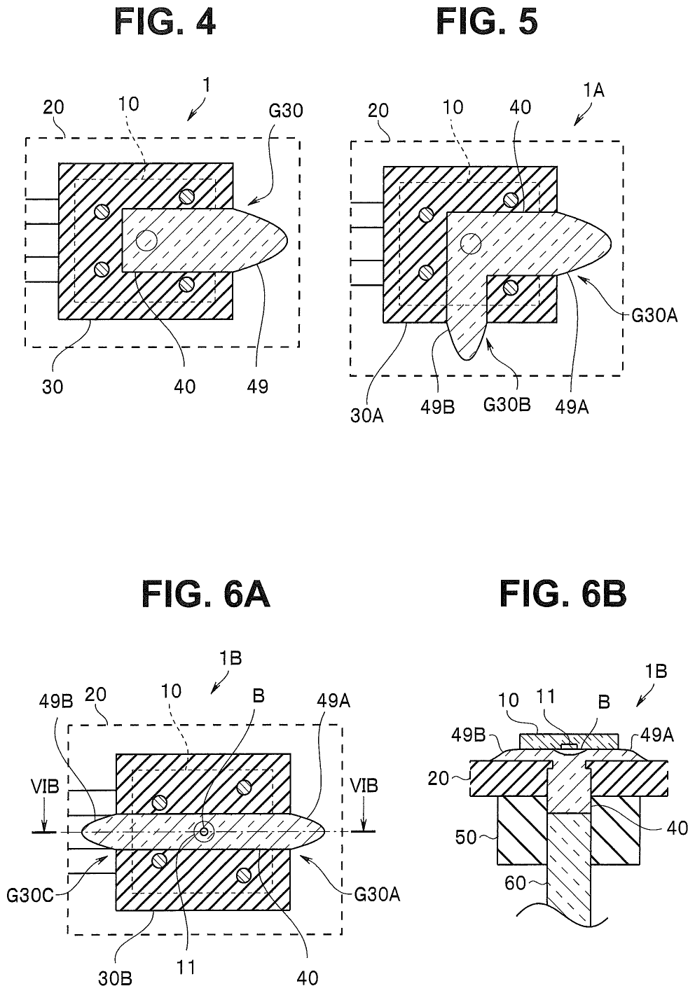

As shown in FIG. 3B, when the optical fiber 60 is inserted in the insertion hole H50, the transparent resin 40 filling inside is pushed toward the optical element 10. The resin layer 30 has the gap G30, so the excessive transparent resin 49 is discharged from the gap G30 and expanded around the resin layer 30 as shown in FIG. 4.

When the liquid transparent resin 40 is pushed toward the optical element 10 and comes in contact with the light emitting face 10SA of the optical element 10, air bubbles may be generated between the liquid transparent resin 40 and the light emitting face 10SA due to the interface tension. In the optical module 1, when the transparent resin 40 is discharged from the gap G30, the air bubbles are also discharged from the gap G30. The air bubbles may remain on an inner peripheral wall and the like of the U-shaped resin layer 30, as long as the air bubbles are discharged from the transparent resin 40 constituting an optical path.

Then, the transparent resin 40 is hardened by ultraviolet radiation or heating. At this time, the transparent resin 40 at the gap between the optical fiber 60 and the insertion hole H50 is also hardened, so that the optical fiber 60 is fixed to the ferrule 50.

The optical module 1 has high light coupling efficiency, because the transparent resin 40 is filled between the optical element 10 and the optical fiber 60 and the air bubbles do not remain in the transparent resin 40 filling the optical path. Furthermore, when the resin layer 30 is made of the light shielding material, there is no influence of outside light, so that transmission quality is high.

Note that an underfill material arranged before the optical element 10 is bonded to the wiring board 20 may be used as the resin layer 30, instead of a side fill material.

After the ferrule 50 is arranged on the wiring board 20, the optical element 10 may be bonded to the wiring board 20, the optical fiber 60 may be inserted, and an excessive refraction index matching agent 40 may be discharged from the gap G30 of the resin layer 30.

In the foregoing, the optical module 1 in which an optical element is a VCSEL having the light emitting portion 11 for outputting light of optical signals has been explained. Needless to say, even when the optical element of the optical module is, for example, a light receiving element such as a photodiode (PD) element having a light receiving portion that is a light function region to which a light of a light signal is inputted, the light receiving element has an effect similar to that of the optical module 1.

### Modification of First Embodiment

Optical modules 1A and 1B in modification of the first embodiment are similar to the optical module 1 and have the same effects, so that components with the same function have the same symbols and explanation thereof will be omitted.

### Modification 1 of First Embodiment

As shown in FIG. 5, in the optical module 1A in Modification 1, two gaps G30A, G30B are arranged in a direction orthogonal to a resin layer 30A arranged to surround an optical path of optical signals.

Therefore, excessive transparent resins 49A and 49B respectively project from gaps G30A and G30B. In other words, the resin layer may have plural gaps. However, the resin layer preferably has a U-shape with one gap because outside light can easily enter an optical path via the gaps.

In an optical module 1B in Modification 2 shown in FIG. 6A and FIG. 6B, two gaps G30A, G30C are arranged at symmetrical positions with an optical path as a center, on a resin layer 30B arranged to surround an optical path.

In the optical module 1B, when the optical fiber 60 is inserted, the resin layer 30 is pushed to a center of the optical path, i.e., in both directions with the light emitting portion 11 of the optical element 10 as a center. Therefore, the optical module 1B has a risk that air bubbles B remain in the optical path.

Therefore, when the resin layer has the plural gaps, like the optical module 1A, the gaps are preferably arranged asymmetrically across the optical path. In other words, it is preferable that there be no other gap and there is a wall of the resin layer at a position point-symmetrical to an optical axis of the gap of the resin layer.

### Second Embodiment

An optical module 1C in a second embodiment is similar to the optical module 1 and the like, and has the same effects, so that components with the same function have the same symbols and explanation thereof will be omitted.

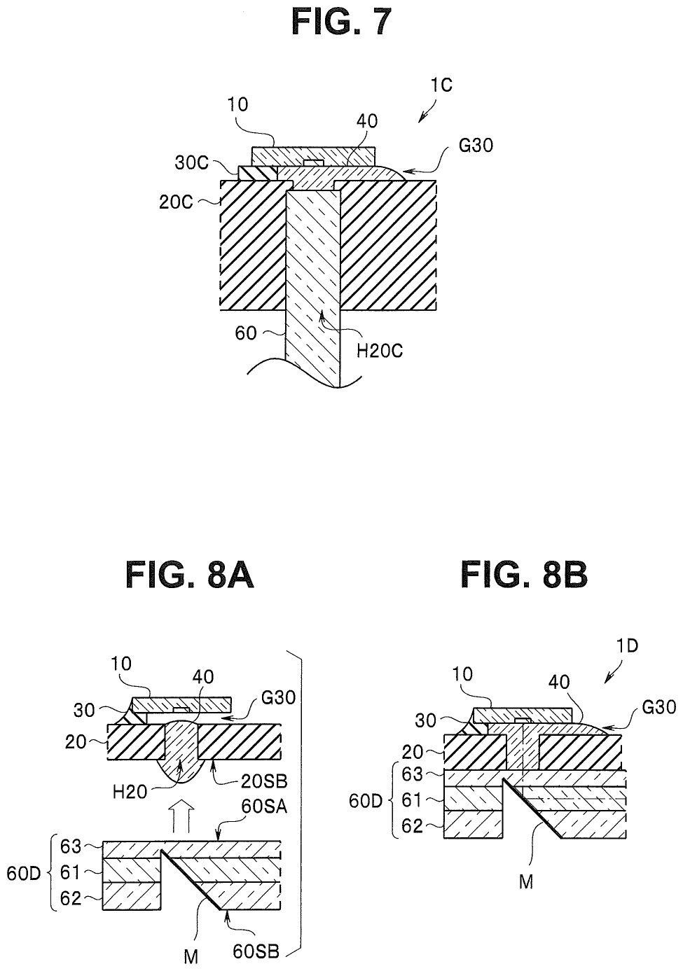

As shown in FIG. 7, the optical module 1C does not include a ferrule unlike the optical module 1. A distal end portion of the optical fiber 60 is inserted in a through hole H20C of the wiring board 20C.

The optical fiber 60 is fixed by the through hole H20C of the wiring board 20C, so that the optical module 1C is shorter and smaller than the optical module 1.

Note that to stably hold the optical fiber 60, thickness of the wiring board 20C is preferably more than twice of the outside diameter of the optical fiber 60. As long as the connection electrode 22 is arranged, the wiring board 20C may be an MID (molded interconnect device) or a ceramic stereoscopic wiring board.

When seen in a different way, the wiring board 20C is a ferrule on which the connection electrode 22 is arranged. In other words, the ferrule in this embodiment has a first main face and a second main face opposite to the first main face, has a connection electrode bonded to an external electrode of an optical element on the first main face, and has a through hole (insertion hole) that is an optical path.

A resin layer 30C of the optical module 1C is an underfill material arranged on a bonding face before the optical element 10 is bonded to the wiring board 20C. The underfill material includes NCP (non-conductive paste) or NCF (non-conductive film). Note that the resin layer 30C is made of a light shielding material similar to the resin layer 30.

The resin layer 30C has a U-shape with the gap G30. When the transparent resin 40 is expanded around the resin layer 30C via the gap G30, air bubbles are discharged from the optical path.

### Third Embodiment

An optical module 1C in a third embodiment is similar to the optical module 1 and has the same effects, so that components with the same function have the same symbols and explanation thereof will be omitted.

As shown in FIG. 8A and FIG. 8B, in the optical module 1D, a light waveguide is a light waveguide board 60D having a third main face 60SA and a fourth main face 60SB opposite to the third main face 60SA. For example, the light waveguide board 60D made of silicon is manufactured using a silicon-on-insulator (SOI) substrate. A silicon layer arranged between silicon oxide layers 62 and 63 is a light waveguide 61 for transmitting optical signals.

In other words, the light waveguide 61 is arranged in parallel to the third main face 60SA and the fourth main face 60SB. Then, the third main face 60SA of the light waveguide board 60D is adhered to the second main face 20SB of the wiring board 20.

The light waveguide board 60D has a reflection face M for optically coupling the light waveguide 61 and the optical element 10. For example, a V-groove with one side inclination angle of 45 degrees is formed from the fourth main face 60SB by dicing saw, so as to form the reflection face M. The reflection face M may be coated with a metallic membrane, and the groove may be filled with the resin.

As shown in FIG. 8A, the liquid transparent resin 40 is arranged inside and around the through hole H20 of the wiring board 20. When the third main face 60SA of the light waveguide board 60D comes into contact with the second main face 20SB of the wiring board 20, the excessive transparent resin 40 is pushed from the gap G30. At this time, air bubbles are also discharged from the gap G30.

Note that the transparent resin 40 that is a refraction index matching material with almost the same refraction index as the light waveguide 61 also has a function as a resin layer for adhering the wiring board 20 to the light waveguide board 60D.

Although not shown, an optical fiber is arranged at an end face of the light waveguide board 60D, and the optical signals generated by the optical element 10 are transmitted via the transparent resin 40, the reflection face M, the light waveguide 61 and the optical fiber.

### Fourth Embodiment

An optical module 1E in a fourth embodiment is similar to the optical module 1C and has the same effects, so that components with the same function have the same symbols and explanation thereof will be omitted.

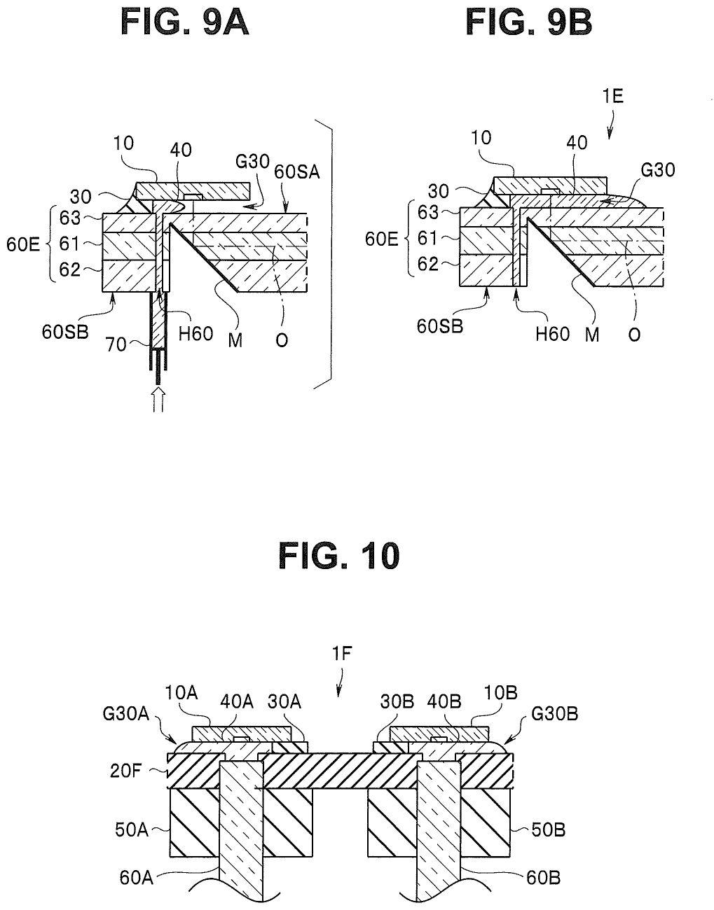

As shown in FIG. 9A and FIG. 9B, in the optical module 1E, a wiring board 60E on which the optical element 10 is mounted is a photoelectric complex wiring board in which the light waveguide 61 is arranged in parallel to the third main face 60SA. In other words, although not shown, a connection electrode bonded to the external electrode 12 of the optical element 10 is arranged on the third main face 60SA of the wiring board 60E.

The wiring board 60E has the reflection face M for optically coupling the light waveguide 61 and the optical element 10. Furthermore, the wiring board 60E has an opening on the fourth main face 60SB, and has an injection hole H60 inserted to the optical path.

As shown in FIG. 9A, the transparent resin 40 is, for example, injected to the injection hole H60 using a micro syringe 70, and is filled in the optical path. As shown in FIG. 9B, the injection hole H60 of the optical module 1E is filled with the transparent resin 40.

After the optical path is filled with the transparent resin 40, the transparent resin 40 continues to be injected. Therefore, the excessive transparent resin 40 is pushed from the gap G30. At this time, air bubbles are also discharged from the gap G30.

### Fifth Embodiment

An optical module 1F in modification of a fifth embodiment is similar to the optical module 1 and has the same effects, so that components with the same function have the same symbols and explanation thereof will be omitted.

As shown in FIG. 10, the optical module 1F has a first optical element 10A and a second optical element 10B. The first optical element 10A is adhered to a wiring board 20F by the resin layer 30A, and an optical path is filled with transparent resin 40A. The second optical element 10B is adhered to the wiring board 20F by the resin layer 30B, and an optical path is filled with transparent resin 40B.

First optical signals generated by the first optical element 10A are transmitted through a first optical fiber 60A inserted in a first ferrule 50A. Second optical signals generated by the second optical element 10B are transmitted through a second optical fiber 60B inserted in a second ferrule 50B.

The excessive transparent resin 40A is discharged from a gap G30A of the resin layer 30A. The excessive transparent resin 40B is discharged from a gap G30B of the resin layer 30B.

Note that the resin layers 30A and 30B are provided so that the gaps G30A and G30B are arranged in opposite directions, i.e., positions not opposite to each other. Therefore, the first optical signals and second optical signals do not interfere with each other.

The resin layers 30A and 30B may be constituted by one resin layer arranged to surround an optical path of the first optical signals and an optical path of the second optical signals.

### Sixth Embodiment

Next, an endoscope 9 in a sixth embodiment will be explained. The endoscope 9 has the optical modules 1 (1A to 1F) at a hard distal end portion 9A of an insertion portion 9B.

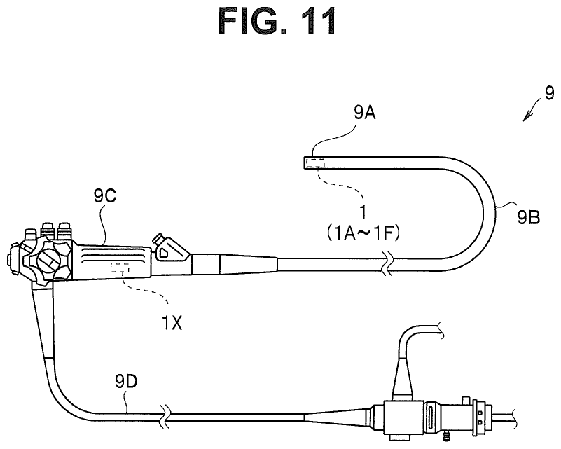

In other words, as shown in FIG. 11, the endoscope 9 includes an insertion portion 9B at which an image pickup portion having an image pickup device with high pixels is arranged at the distal end portion 9A, an operation portion 9C arranged on a base end side of the insertion portion 9B, and a universal code 9D extending from the operation portion 9C.

Electric signals outputted by the image pickup portion are converted to optical signals by the optical modules 1 (1A to 1F) in which an optical element is a planar light emission laser, are converted again to electric signals by an optical module 1X in which an optical element arranged at the operation portion 9C via the optical fiber 60 is PD, and are transmitted via a metal wiring. In other words, signals are transmitted via the optical fiber 60 in the insertion portion 9B with a small diameter.

As already explained, the optical modules 1(1A to 1F) have high light coupling efficiency and high transmission quality. Therefore, the endoscope 9 can display high-quality images.

Note that the optical module 1X is arranged at the operation portion 9C with a comparatively large arrangement space, but preferably has the same components as the optical module 1 and the like according to the present invention.

The present invention is not limited to the abovementioned embodiments, but various changes, combinations and applications can be made in a range not departed from a gist of the invention.

What is claimed is:

1. An optical module comprises:
an optical element having a light function region for emitting or receiving optical signals, and an external electrode on a top face;
a wiring board having a first main face and a second main face, having a connection electrode bonded to the external electrode of the optical element on the first main face, and having a through hole serving as an optical path of the optical signals;
a light waveguide for transmitting the optical signals, the light waveguide being arranged at a position coupled optically to the optical element;
a resin layer sealing a bonding portion between the external electrode and the connection electrode, constituting a wall surrounding the optical path, and having at least one gap serving as a break on the wall, and
transparent resin filling the optical path between the optical element and the light waveguide,
wherein the transparent resin is expanded around the resin layer via at least one gap of the resin layer.

2. The optical module according to claim 1, wherein the resin layer has a light shielding property.

3. The optical module according to claim 1, wherein the at least one gap is one gap, and the resin layer is a U-shaped cross section orthogonal to the optical path.

4. The optical module according to claim 1, wherein the at least one gap are plural gaps, and the plural gaps are arranged asymmetrically with the optical path as a center.

5. The optical module according to claim 1, wherein the light waveguide is an optical fiber;
wherein the optical module further comprises a ferrule having an insertion hole in which a distal end portion of the optical fiber is inserted; and
wherein the ferrule is arranged on the second main face of the wiring board.

6. The optical module according to claim 1, wherein the light waveguide is an optical fiber, and a distal end portion of the optical fiber is inserted in the through hole of the wiring board.

7. The optical module according to claim 1, further comprising a light waveguide board having a third main face and a fourth main face, wherein the light waveguide is arranged in parallel to the third main face and adhered to the second main face of the wiring board, and
wherein the light waveguide board has a reflection face for optically coupling the light waveguide and the optical element.

8. The optical module according to claim 1, wherein the wiring board is a photoelectric complex wiring board in which the light waveguide is arranged in parallel to the first main face,
wherein the photoelectric complex wiring board has a reflection face for optically coupling the light waveguide and the optical element, and
wherein an injection hole having an opening on the second main face and inserted to the optical path is filled with the transparent resin.

9. The optical module according to claim 1, comprising a first optical element and a second optical element, wherein the first optical element and the second optical element are adhered to the wiring board by the respective resin layer, and the respective optical paths are filled with the respective transparent resins.

10. The optical module according to claim 9, wherein the respective resin layers are arranged at positions such that the gaps are not opposite to each other.

11. An endoscope having an optical module, wherein the optical module comprises:
an optical element having a light function region for emitting or receiving optical signals, and an external electrode on a top face;
a wiring board having a first main face and a second main face, having a connection electrode bonded to the external electrode of the optical element on the first main face, and having a through hole serving as an optical path of the optical signals;
a light waveguide for transmitting the optical signals, the light waveguide being arranged at a position coupled optically to the optical element;
a resin layer sealing a bonding portion between the external electrode and the connection electrode, constituting a wall surrounding the optical path, and having at least one gap serving as a break on the wall, and
transparent resin filling the optical path between the optical element and the light waveguide,
wherein the transparent resin is expanded around the resin layer via at least one gap of the resin layer.
